(19) United States
(12) Patent Application Publication
(10) Pub. No.: US 2025/0079336 A1
(43) Pub. Date: Mar. 6, 2025

(54) STRESS AND WARPAGE MODULATING STRUCTURE FOR MULTI-STACKED WAFER AND DIE LEVEL BONDING PACKAGES

(71) Applicant: TAIWAN SEMICONDUCTOR MANUFACTURING COMPANY, LTD., Hsinchu (TW)

(72) Inventors: Sung-Hsin YANG, Hsinchu (TW); Jen-Yuan CHANG LIN, Hsinchu (TW); Chen-Chieh CHIANG, Hsinchu (TW); Chuan-Cheng TSOU, Hsinchu (TW)

(21) Appl. No.: 18/459,089

(22) Filed: Aug. 31, 2023

(51) Int. Cl. H01L 23/00; H01L 21/02; H01L 21/3105; H01L 21/67

(52) U.S. Cl. CPC H01L 23/562; H01L 21/0214; H01L 21/02255; H01L 21/02274; H01L 21/31053; H01L 21/67098; H01L 21/67276

(57) ABSTRACT

A stress modulating device including a semiconductor substrate, a first insulating layer formed over a first side of the semiconductor substrate, a second insulating layer formed over the first insulating layer, a third insulating layer formed over a second side of the semiconductor substrate, a fourth insulating layer formed over the third insulating layer, and a fifth insulating layer formed over the fourth insulating layer for incorporation in multi-stack package assemblies for reducing stress, strain, and/or warpage on the active elements within the package assembly.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, improved performance, and lower costs, challenges from both fabrication and design issues have resulted in the development of a number of three-dimensional designs including, for example, Metal-Oxide-Silicon Field Effect Transistors (MOS-FET), Field Effect Transistors (FET), Fin Field Effect Transistor (FinFET), Gate-All-Around (GAA) devices (nanowires/nanosheets), GAA devices configured as Complementary Field Effect Transistor (CFET) devices, and Multi-Bridge Channel Field Effect Transistor (MBCFET) devices (nanosheets).

Integrated circuit (IC) manufacturing processes are divided into front-end-of-line (FEOL) processing and back-end-of-line (BEOL) processing, in some instances. FEOL processes generally encompass those processes related to fabricating functional elements, such as transistors and resistors, in or on a semiconductor substrate. For example, FEOL processes typically include forming isolation features, gate electrodes and dielectrics, and source and drain features (also referred to as source/drain or S/D features). BEOL processes generally encompass those processes related to fabricating a multilayer interconnect (MLI) features that interconnects the functional IC elements and structures fabricated during FEOL processing to provide connection to and enable operation of the resulting IC devices.

Stress analysis and control at both chip and package levels is becoming more of a consideration as dimensions continue to shrink and the use of chip-on-chip and chip-on-wafer assemblies increases. The reduction of stress and warpage between and across semiconductor components will tend to improve performance and the reliability of the resulting semiconductor devices. The chips, packages, and/or boards in stacked packages are each a potential source of structural and thermal stress that tend to increase along with the level of integration and complexity. Process and/or structural modifications that reduce and/or compensate for some of the mechanical and thermal stresses resulting from the selection and configuration of the material layers, bonding structures, semiconductor devices, complex assemblies, and/or the operation of such devices are helpful in reducing defects, improving performance, and/or increasing the lifetime of the resulting devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-C are cross-sectional views of a stress and warpage modulating structure (SWM structure) during a manufacturing process, according to some embodiments.

FIG. 1D is a flowchart of a portion of a manufacturing process for the production of SWM structures according to some embodiments of the structures of FIGS. 1A-C.

FIGS. 2A-C are cross-sectional views of a stress and warpage modulating structure (SWM structure) during a manufacturing process, according to some embodiments.

FIG. 2D is a flowchart of a portion of a manufacturing process for the production of SWM structures according to some embodiments of the structures of FIGS. 2A-C.

FIGS. 3A-D are cross-sectional views of a stress and warpage modulating structure (SWM structure) during a manufacturing process, according to some embodiments.

FIG. 3E is a flowchart of a portion of a manufacturing process for the production of SWM structures according to some embodiments of the structures of FIGS. 3A-D.

FIGS. 4A-D are cross-sectional views of a stress and warpage modulating structure (SWM structure) during a manufacturing process, according to some embodiments.

FIG. 4E is a flowchart of a portion of a manufacturing process for the production of SWM structures according to some embodiments of the structures of FIGS. 4A-D.

FIGS. 5A-E are cross-sectional views of a stress and warpage modulating structure (SWM structure) during a manufacturing process, according to some embodiments.

FIG. 5F is a flowchart of a portion of a manufacturing process for the production of SWM structures according to some embodiments of the structures of FIGS. 5A-E.

FIGS. 6A-H are cross-sectional views of a multi-stack wafer/die level package during a manufacturing process that incorporates a SWM structure according to some embodiments.

FIGS. 7A-D are cross-sectional views of embodiments of multi-stack wafer/die level packages incorporating a SWM structure.

FIGS. 8A-H are cross-sectional views of a multi-stack wafer/die level package during a manufacturing process that incorporates a SWM structure according to some embodiments.

FIG. 9 is a cross-sectional view of a multi-stack wafer/die system of integrated chips (SOIC) package during a manufacturing process that incorporates a SWM structure according to some embodiments.

FIG. 10 is a block diagram of an electronic process control (EPC) system useful for the production of CFET devices according to some embodiments.

FIG. 11 is a block diagram of a system for manufacturing CFET devices according to some embodiments.

FIG. 12 is a block diagram of fabrication facility operations for manufacturing of IC devices according to some embodiments.

### DETAILED DESCRIPTION

The following disclosure provides many different embodiments, or examples, for implementing different features of the provided subject matter. Specific examples of components, values, operations, materials, arrangements or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first are formed in direct contact the second features and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

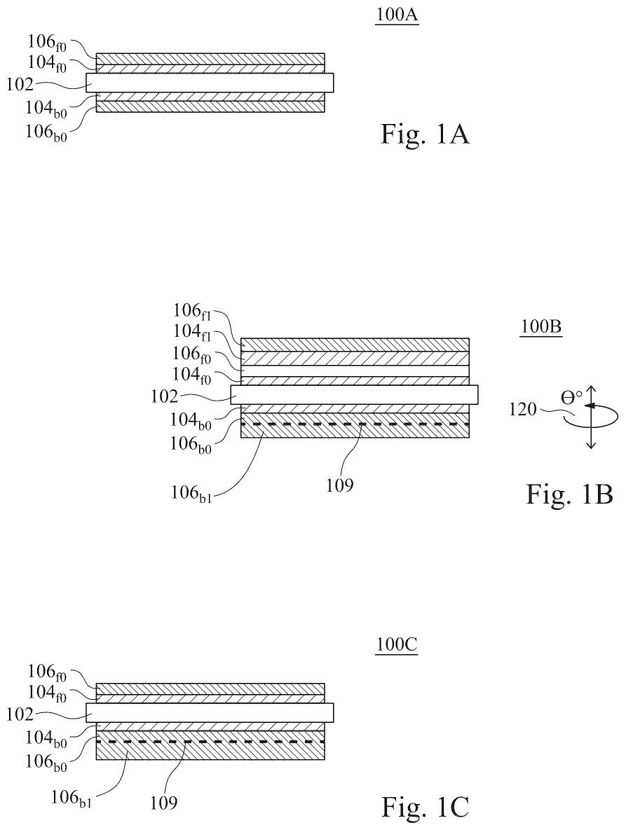

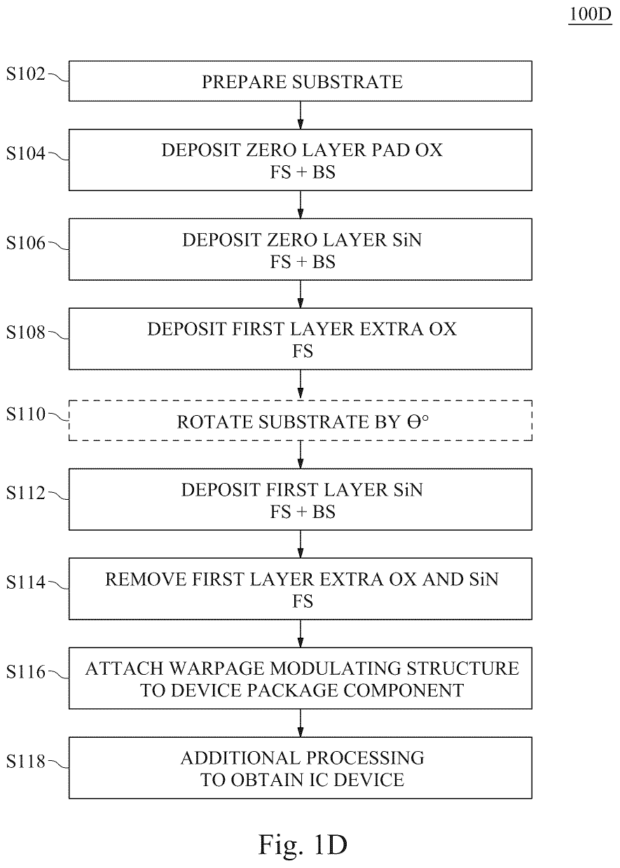

FIGS. 1A-C are cross-sectional views of a stress and warpage modulating structure (SWM structure) during a manufacturing process, according to some embodiments. In FIG. 1A a semiconductor substrate 102 is prepared and a frontside pad oxide layer 10_{f0} and a backside pad oxide layer 104_{b0} are formed on opposing sides of the semiconductor substrate. The pad oxide layers will typically be formed using a process selected from atomic layer deposition (ALD), physical vapor deposition (PVD), chemical vapor deposition CVD, plasma enhanced chemical vapor deposition (PECVD), thermal oxidation, self-aligned monolayer (SAM) deposition and/or one or more other suitable method(s) and, in some embodiments, will comprise suitable materials in addition to or other than silicon dioxide. In some embodiments the frontside pad oxide layer 104_{f0} and a backside pad oxide layer 104_{b0} have a thickness of about 40 Å although layers having other thicknesses are used in some embodiments. In some embodiments, the pad oxide layers are formed using a thermal oxidation process to obtain an oxide layer having a thickness of 10-200 Å. Oxide layers of less than 10 Å tend to have reduced dielectric performance and/or undesirable variations in the thickness across the wafer. Oxide layers of greater than 200 Å tend to increase processing time without a corresponding improvement in the performance of the resulting layer and/or cause issues during downstream processing.

A frontside silicon nitride layer 106_{f0} and a backside silicon nitride layer 106_{b0} are then formed on the corresponding frontside pad oxide layer 104_{f0} and a backside pad oxide layer 104_{b0}. In some embodiments the silicon nitride layers have a thickness of about 380 Å although layers having other thicknesses are used in some embodiments. The silicon nitride layers will typically be formed using a process selected from atomic layer deposition (ALD), physical vapor deposition (PVD), chemical vapor deposition CVD, plasma enhanced chemical vapor deposition (PECVD), thermal oxidation, self-aligned monolayer (SAM) deposition and/or one or more other suitable method(s) and, in some embodiments, will comprise suitable materials in addition to or other than silicon nitride. The semiconductor substrate 102, in combination with the frontside pad oxide layer 104_{f0}, the backside pad oxide layer 104_{b0}, the frontside silicon nitride layer 106_{f0}, and the backside silicon nitride layer 106_{b0} comprise a zero layer structure 100A. In some embodiments, the silicon nitride layers are formed using a thermal nitridation process to obtain a silicon nitride layer having a thickness of 100-2000 Å. In some embodiments, the relative thicknesses of the pad oxide and silicon nitride layers are selected to provide an oxide:nitride thickness ratio of 1:9 to 1:10. Nitride layers of less than 100 Å tend to have reduced dielectric performance and/or undesirable variations in the thickness across the wafer. Nitride layers of greater than 2000 Å tend to increase processing time without a corresponding improvement in the performance of the resulting layer and/or cause issues during downstream processing. Relative thicknesses of the pad oxide and silicon nitride layers resulting in a oxide:nitride thickness ratio greater than 1:9 or less than 1:10 tend to have reduced dielectric and/or mechanical performance when compared with those combinations having relative thicknesses within the range of 1:9 and 1:10.

In FIG. 1B, the zero layer structure 100A is modified by the addition of a first frontside extra oxide layer 104_{f1} and a first frontside silicon nitride layer 106_{f1}. In some embodiments, a first frontside extra oxide layer 104_{f1} has a thickness of about 100 Å although layers having other thicknesses are used in some embodiments. The zero layer structure is further modified by the addition of a first backside silicon nitride layer 106_{b1} that is formed over the backside silicon nitride layer 106_{b0} without an intervening oxide layer with an interface 109 and provide a double nitride layer 106_{b0}+106_{b1} on the backside of the first layer structure 100B. In some embodiments, the first frontside silicon nitride layer 106_{f1} and the first backside silicon nitride layer 106_{b1} have a thickness of about 380 Å although one or both of the first silicon nitride layers having other thicknesses are used in some embodiments. In some embodiments, the zero layer structure 100A is rotated to a predetermined offset angle 120 that is Θ degrees offset from the orientation used during formation of the underlying layer(s). In some embodiments, the offset angle is between 0° and 90°. In some embodiments, successive depositions are conducted at offset angles of 15°, 30°, 45°, 60°, 75°, or 90°. In some embodiments, the specific equipment utilized for rotating the substrate to create the predetermined Θ degree offset angle will have inherent mechanical interference positions that define forbidden angles of rotation for the specific equipment. Using the machine-specific information, the range of acceptable values for the predetermined Θ degree offset angle for processes utilizing such machines will be adjusted accordingly to exclude the forbidden angles. In some embodiments, a narrow range of values on either side of the forbidden angles will also be excluded to ensure proper operation of the machine.

In FIG. 1C, the first layer structure 100B is modified by removing the first frontside extra oxide layer 104_{f1} and a first frontside silicon nitride layer 106_{f1} to form a SWM structure 100C. In some embodiments, the pad oxide and silicon nitride layers are removed using a dry-etch or plasma etch process. In some embodiments, plasma etching (PE) or reactive ion etching (RIE) of a substrate material(s) is/are performed using halogen-containing reactive gasses excited by an electromagnetic field to dissociate into ions. Reactive or etchant gases include, for example, CF₄, SF₆, NF₃, Cl₂, CCl₂F₂, SiCl₄, BCl₂, or combinations thereof, although other semiconductor-material etchant gases are also envisioned within the scope of the present disclosure. In some embodiments, at least one of the substrate materials is wholly or partially removed using a wet etch in which a liquid chemical etch solution including one or more etchants such as citric acid (C₆H₈O₇), hydrogen peroxide (H₂O₂), nitric acid (HNO₃), sulfuric acid (H₂SO₄), hydrochloric acid (HCl), acetic acid (CH₃CO₂H), hydrofluoric acid (HF), buffered hydrofluoric acid (BHF), phosphoric acid (H₃PO₄), ammonium fluoride (NH₄F) potassium hydroxide (KOH), ethylenediamine pyrocatechol (EDP), TMAH (tetramethylammonium hydroxide), or a combination thereof is used to remove the target material(s).

FIG. 1D is a flowchart of a portion of a manufacturing process 100D for the production of SWM structures according to some embodiments of the structures of FIGS. 1A-C including operation S102 during which the semiconductor substrate is prepared for pad oxide deposition, operation S104 during which the zero layer pad oxide layers are formed on both the frontside (FS) and backside (BS) surfaces of the semiconductor substrate 102 and operation S106 during which the zero layer silicon nitride layers are formed on both the FS and BS surfaces of the semiconductor substrate 102 to complete the zero layer structure 100A. The zero layer structure 100A is then further modified in operation S108 during which the first layer extra oxide is formed on the FS of the zero layer structure 100A, followed by an optional operation S110 during which the zero layer structure 100A is rotated to an offset angle of Θ°, e.g., 45°, and operation S112 during which the first layer silicon nitride is deposited on the FS and BS of the zero layer structure 100A to complete first layer structure 100B. In operation S114 the first layer of silicon nitride and the first layer of extra oxide are removed from the FS of the first layer structure 100B to complete an embodiment of a SWM structure 100C. The SWM structure 100C can then be utilized in multi-stacked die/wafer and wafer/wafer comprising systems of integrated chips (SOIC) and chip on wafer on substrate (CoWoS) packaging configurations.

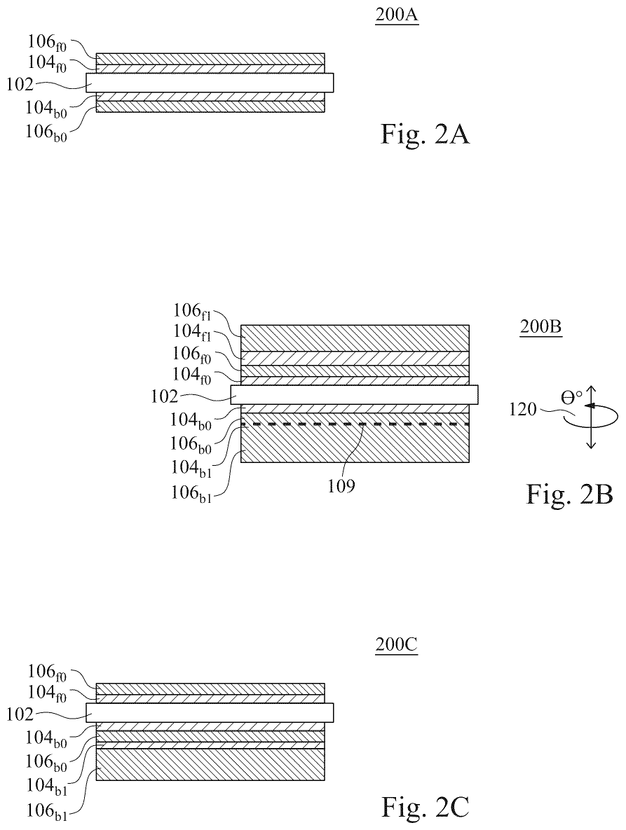

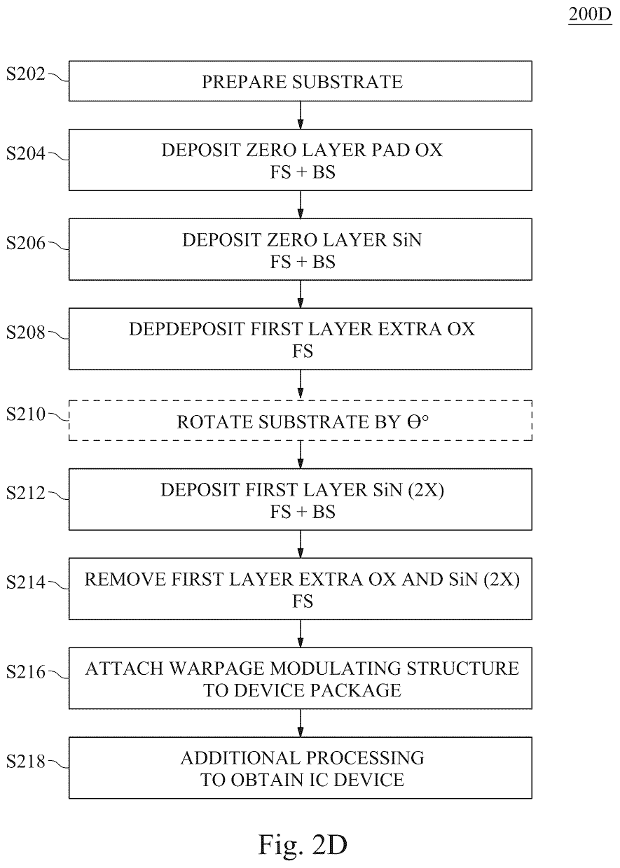

FIGS. 2A-C are cross-sectional views of a stress and warpage modulating structure (SWM structure) during a manufacturing process, according to some embodiments. In FIG. 2A a semiconductor substrate 102 is prepared and a frontside pad oxide layer 104_{f0} and a backside pad oxide layer 104_{b0} are formed on opposing sides of the semiconductor substrate. The pad oxide layers will typically be formed using one or more of the processes discussed above in connection with FIG. 1A and, in some embodiments, will comprise suitable materials in addition to or other than silicon dioxide. In some embodiments the frontside pad oxide layer 104_{f0} and a backside pad oxide layer 104_{b0} have a thickness of about 40 Å although pad oxide layers having other thicknesses are used in some embodiments.

A frontside silicon nitride layer 106_{f0} and a backside silicon nitride layer 106_{b0} are then formed on the corresponding frontside pad oxide layer 104_{f0} and a backside pad oxide layer 104_{b0}. In some embodiments the silicon nitride layers have a thickness of about 380 Å although layers having other thicknesses are used in some embodiments. The silicon nitride layers will typically be formed using a process using one or more of the processes discussed above in connection with FIG. 1A and, in some embodiments, will comprise suitable materials in addition to or other than silicon nitride. The semiconductor substrate 102, in combination with the frontside pad oxide layer 104_{f0}, the backside pad oxide layer 104_{b0}, the frontside silicon nitride layer 106_{f0}, and the backside silicon nitride layer 106_{b0} comprise a zero layer structure 200A.

In FIG. 2B the zero layer structure 200A is modified by the addition of a first frontside extra oxide layer 104_{f1} and a first frontside silicon nitride layer 106_{f1}. In some embodiments a first frontside extra oxide layer 104_{f1} has a thickness of about 100 Å although layers having other thicknesses are used in some embodiments. The zero layer structure is further modified by the addition of a first backside silicon nitride layer 106_{b1} that is formed over the backside silicon nitride layer 106_{b0} without an intervening oxide layer with an interface 109 and provide a double nitride layer 106_{b0}+106_{b1} on the backside of the first layer structure 100B. In some embodiments the first frontside silicon nitride layer 106_{f1} and the first backside silicon nitride layer 106_{b1} have a thickness of about 200-2000 Å, e.g., 800 Å, although one or both of the first silicon nitride layers having other thicknesses are used in some embodiments. In some embodiments the zero layer structure 200A is rotated to a predetermined offset angle 120 that is Θ degrees offset from the orientation used during formation of the underlying layer(s). In some embodiments the offset angle is between 0° and 90°. In some embodiments, successive depositions are conducted at offset angles of 15°, 30°, 45°, 60°, 75°, or 90°.

In FIG. 2C the first layer structure 200B is modified by removing the first frontside extra oxide layer 104_{f1} and a first frontside silicon nitride layer 106_{f1} to form a SWM structure 200C. In some embodiments, the extra oxide and silicon nitride layers are removed using a dry-etch, plasma etch, and/or wet etch processes as detailed above with reference to FIG. 1C.

FIG. 2D is a flowchart of a portion of a manufacturing process 200D for the production of SWM structures according to some embodiments of the structures of FIGS. 2A-C including operation S202 during which the semiconductor substrate is prepared for pad oxide deposition, operation S204 during which the zero layer pad oxide layers are formed on both the frontside (FS) and backside (BS) surfaces of the semiconductor substrate 102 and operation S206 during which the zero layer silicon nitride layers are formed on both the FS and BS surfaces of the semiconductor substrate 102 to complete the zero layer structure 200A. The zero layer structure 200A is then further modified in operation S208 during which the first layer extra oxide is formed on the FS of the zero layer structure 200A, followed by an optional operation S210 during which the zero layer structure 200A is rotated to an offset angle of Θ°, e.g., 45°, and operation S212 during which the thicker first layer silicon nitride is deposited on the FS and BS of the zero layer structure 200A to complete first layer structure 200B. In operation S214, the first layer silicon nitride and the first layer extra oxide are removed from the FS of the first layer structure 200B are removed to complete an embodiment of a SWM structure 200C. The SWM structure 200C can then be utilized in multi-stacked die/wafer and wafer/wafer comprising systems of integrated chips (SOIC) and chip on wafer on substrate (CoWoS) packaging configurations.

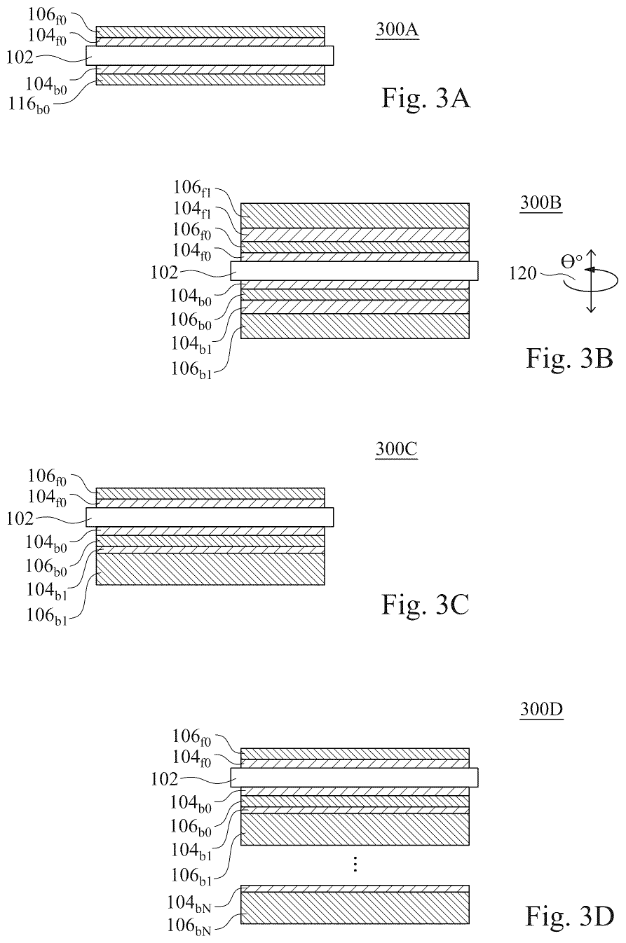

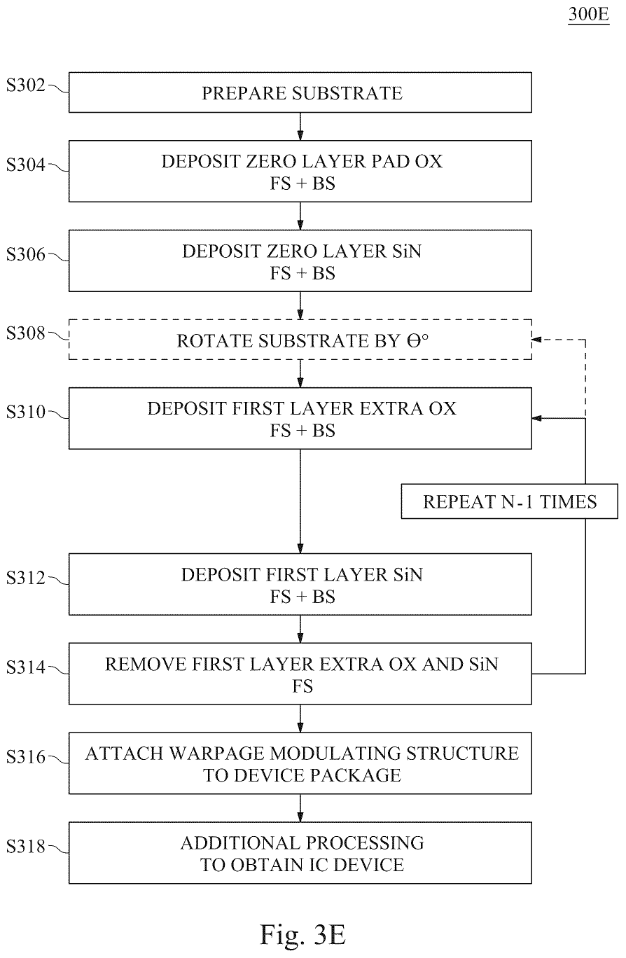

FIGS. 3A-D are cross-sectional views of a stress and warpage modulating structure (SWM structure) during a manufacturing process, according to some embodiments. In FIG. 3A a semiconductor substrate 102 is prepared and a frontside pad oxide layer 104_{f0} and a backside pad oxide layer 104_{b0} are formed on opposing sides of the semiconductor substrate. The pad oxide layers will typically be formed using one or more of the processes discussed above in connection with FIG. 1A and, in some embodiments, will comprise suitable materials in addition to or other than silicon dioxide. In some embodiments the frontside pad oxide layer 104_{f0} and a backside pad oxide layer 104_{b0} have a thickness of about 40 Å although pad oxide layers having other thicknesses are used in some embodiments.

A frontside silicon nitride layer 106_{f0} and a backside silicon nitride layer 106_{b0} are then formed on the corresponding frontside pad oxide layer 104_{f0} and a backside pad oxide layer 104_{b0}. In some embodiments the silicon nitride layers have a thickness of about 380 Å although layers having other thicknesses are used in some embodiments. The silicon nitride layers will typically be formed using a process using one or more of the processes discussed above in connection with FIG. 1A and, in some embodiments, will comprise suitable materials in addition to or other than silicon nitride. The semiconductor substrate 102, in combination with the frontside pad oxide layer 104_{f0}, the backside pad oxide layer 104_{b0}, the frontside silicon nitride layer 106_{f0}, and the backside silicon nitride layer 106_{b0} comprise a zero layer structure 300A.

In FIG. 3B, the zero layer structure 300A is modified by the addition of a first frontside extra oxide layer 104_{f1} and a first frontside silicon nitride layer 106_{f1}. In some embodiments the first frontside extra oxide layer 104_{f1} has a thickness of about 20-200 Å although layers having other thicknesses are used in some embodiments. The zero layer structure is further modified by the addition of a first backside extra oxide layer 104_{b1} and a first backside silicon nitride layer 106_{b1} that is formed over the backside silicon nitride layer 106_{b0} on the backside of the first layer structure 300B. In some embodiments, the first backside extra oxide layer 104_{b1} has a thickness of about 20-200 Å although layers having other thicknesses are used in some embodiments. In some embodiments, the first frontside silicon nitride layer 106_{f1} and first backside silicon nitride layer 106_{b1} have a thickness of about 200-2000 Å, e.g., 800 Å, although one or both of the first silicon nitride layers having other thicknesses are used in some embodiments. In some embodiments the zero layer structure 300A is rotated to a predetermined offset angle 120 that is Θ degrees offset from the orientation used during formation of the underlying layer(s). In some embodiments the offset angle is between 0° and 90°. In some embodiments, successive depositions are conducted at offset angles of 15°, 30°, 45°, 60°, 75°, or 90°.

In FIG. 3C, the first layer structure 300B is modified by removing the first frontside extra oxide layer 104_{f1} and a first frontside silicon nitride layer 106_{f1} to form an intermediate SWM structure 300C. In some embodiments, the extra oxide and silicon nitride layers are removed using a dry-etch, plasma etch, and/or wet etch processes as detailed above with reference to FIG. 1C.

In FIG. 3D, the intermediate SWM structure 300C is modified by the repeated formation of additional N−1 frontside extra oxide layers 104_{fN-1}, backside extra oxide layers 104_{bN-1}, frontside silicon nitride layers 106_{fN-1}, and backside silicon nitride layers 106_{bN-1} as detailed above with reference to FIG. 3B. The additional depositions are then followed by removing each of the additional N−1 frontside extra oxide layers 104_{fN-1} and frontside silicon nitride layers 106_{fN-1} to form SWM structure 300D in which the backside of the SWM structure 300D includes N layers of alternating layers of backside extra oxide layers 104_{bN} and backside silicon nitride layers 106_{bN}. In some embodiments, the extra oxide and silicon nitride layers are removed using a dry-etch, plasma etch, and/or wet etch processes as detailed above with reference to FIG. 1C.

FIG. 3E is a flowchart of a portion of a manufacturing process 300E for the production of SWM structures according to some embodiments of the structures of FIGS. 3A-D including operation S302 during which the semiconductor substrate is prepared for pad oxide deposition, operation S304 during which the zero layer pad oxide layers are formed on both the frontside (FS) and backside (BS) surfaces of the semiconductor substrate 102 and operation S306 during which the zero layer silicon nitride layers are formed on both the FS and BS surfaces of the semiconductor substrate 102 to complete the zero layer structure 300A. The zero layer structure 300A is then passed into optional operation S308 during which the zero layer structure 300A is rotated to an offset angle of Θ°, e.g., 45°, and operation S310 during which the first layer extra oxide is formed on the FS of the zero layer structure 300A, and operation S312 during which the thicker first layer silicon nitride is deposited on the FS and BS of the zero layer structure 200A to complete first layer structure 200B. In operation S214 the first layer silicon nitride and the first layer extra oxide are removed from the FS of the first layer structure 200B are removed to complete an embodiment of a SWM structure 200C. The SWM structure 200C can then be utilized in multi-stacked die/wafer and wafer/wafer comprising systems of integrated chips (SOIC) and chip on wafer on substrate (CoWoS) packaging configurations.

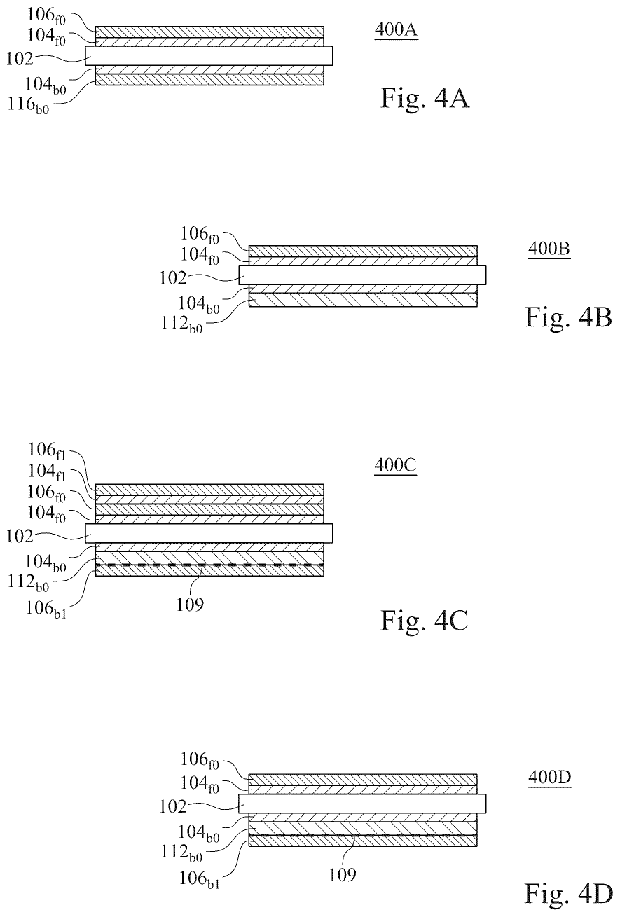

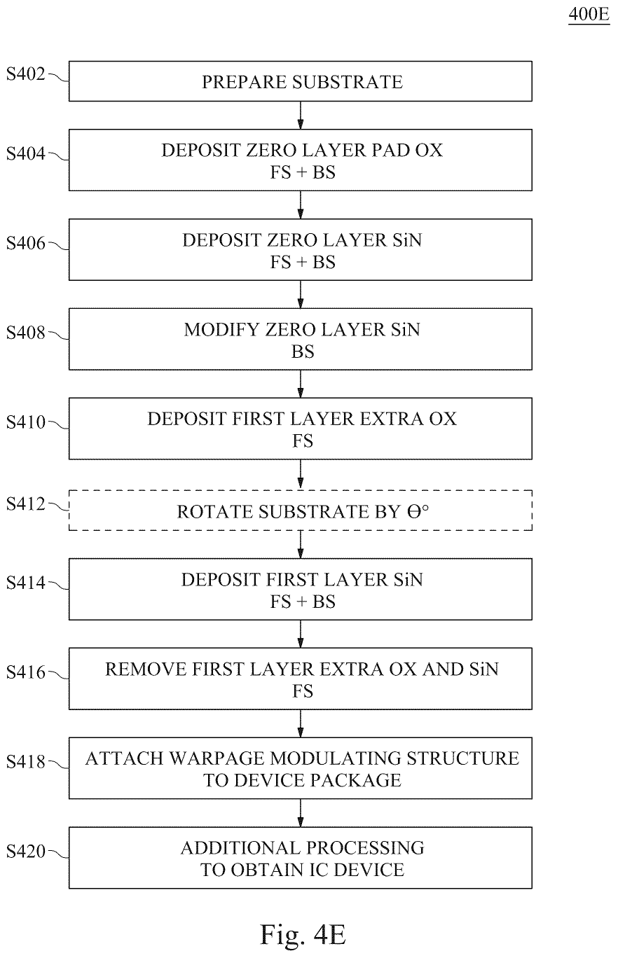

FIGS. 4A-D are cross-sectional views of a stress and warpage modulating structure (SWM structure) during a manufacturing process, according to some embodiments. In FIG. 4A, a semiconductor substrate 102 is prepared and a frontside pad oxide layer 104_{f0} and a backside pad oxide layer 104_{b0} are formed on opposing sides of the semiconductor substrate. The pad oxide layers will typically be formed using one or more of the processes discussed above in connection with FIG. 1A and, in some embodiments, will comprise suitable materials in addition to or other than silicon dioxide. In some embodiments the frontside pad oxide layer 104_{f0} and a backside pad oxide layer 104_{b0} have a thickness of about 40 Å although pad oxide layers having other thicknesses are used in some embodiments.

A frontside silicon nitride layer 106_{f0} and a backside silicon nitride layer 106_{b0} are then formed on the corresponding frontside pad oxide layer 104_{f0} and a backside pad oxide layer 104_{b0}. In some embodiments the silicon nitride layers have a thickness of about 380 Å although layers having other thicknesses are used in some embodiments. The silicon nitride layers will typically be formed using a process using one or more of the processes discussed above in connection with FIG. 1A and, in some embodiments, will comprise suitable materials in addition to or other than silicon nitride. The semiconductor substrate 102, in combination with the frontside pad oxide layer 104_{f0}, the backside pad oxide layer 104_{b0}, the frontside silicon nitride layer 106_{f0}, and the backside silicon nitride layer 106_{b0} comprise a zero layer structure 400A.

In FIG. 4B, the zero layer structure 400A is modified by the implanting oxygen into the backside silicon nitride layer 106_{b0} to obtain a SiON composition (alternatively SiN:OX) forming a backside SiN:OX layer 112_{b0} in place of the initially formed backside silicon nitride layer 106_{b0} to form an intermediate SWM structure 400B. In some embodiments the backside SiN:OX layer 112_{b0} will have a thickness similar to that of the initially deposited of about 380 Å although layers having other thicknesses are used in some embodiments.

In FIG. 4C, the intermediate SWM structure 400B is then modified by the addition of a first frontside extra oxide layer 104_{f1} and a first frontside silicon nitride layer 106_{f1} to form a first layer structure 400C. In some embodiments the first frontside extra oxide layer 104_{f1} has a thickness of about 20-200 Å, e.g., 40 Å, although layers having other thicknesses are used in some embodiments. The intermediate SWM structure 400B is further modified by the addition of a first backside silicon nitride layer 106_{b1} that is formed over the backside SiN:OX layer 112_{b0} on the backside of the intermediate SWM structure 400B. In some embodiments the first frontside silicon nitride layer 106_{f1} and first backside silicon nitride layer 106_{b1} have a thickness of about 200-2000 Å, e.g., 800 Å, although one or both of the first silicon nitride layers having other thicknesses are used in some embodiments. In some embodiments the intermediate SWM structure 400B is rotated to a predetermined offset angle that is Θ degrees offset from the orientation used during formation of the underlying layer(s) between the formation of successive layers. In some embodiments the offset angle is between 0° and 90°. In some embodiments, successive depositions are conducted at offset angles of 15°, 30°, 45°, 60°, 75°, or 90°.

In FIG. 4D, the first layer structure 400C is modified by removing the first frontside extra oxide layer 104_{f1} and a first frontside silicon nitride layer 106_{f1} to form a SWM structure 400D. In some embodiments, the extra oxide and silicon nitride layers are removed using a dry-etch, plasma etch, and/or wet etch processes as detailed above with reference to FIG. 1C.

FIG. 4E is a flowchart of a portion of a manufacturing process 400E for the production of SWM structures according to some embodiments of the structures of FIGS. 4A-D including operation S402 during which the semiconductor substrate is prepared for pad oxide deposition, operation S404 during which the zero layer pad oxide layers are formed on both the frontside (FS) and backside (BS) surfaces of the semiconductor substrate 102 and operation S406 during which the zero layer silicon nitride layers are formed on both the FS and BS surfaces of the semiconductor substrate 102 to complete the zero layer structure 400A. In operation S408, the BS silicon nitride layer of the zero layer structure 400A is implanted with oxygen to convert the initially deposited silicon nitride into a SiN:OX material. In operation S410 the first layer extra oxide is formed on the FS of the intermediate SWM structure 400B and then passed into optional operation S412 during which the intermediate SWM structure 400B is rotated to an offset angle of Θ°, e.g., 45°, and operation S414 during which the first silicon nitride layers are formed on the FS and BS of the intermediate SWM structure 400B. In operation S416 the first layer silicon nitride and the first layer extra oxide are removed from the FS of the first layer structure 400C to complete an embodiment of a SWM structure 400D. The SWM structure 400D is then ready to be used as a structural component in multi-stacked die/wafer and wafer/wafer comprising, e.g., systems of integrated chips (SOIC) and chip on wafer on substrate (CoWoS) packaging configurations.

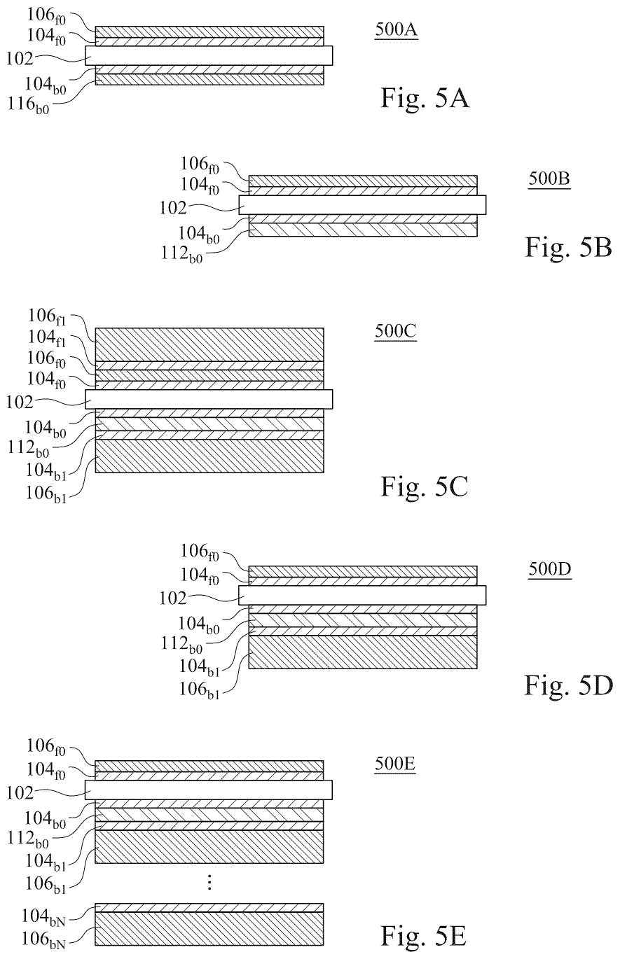

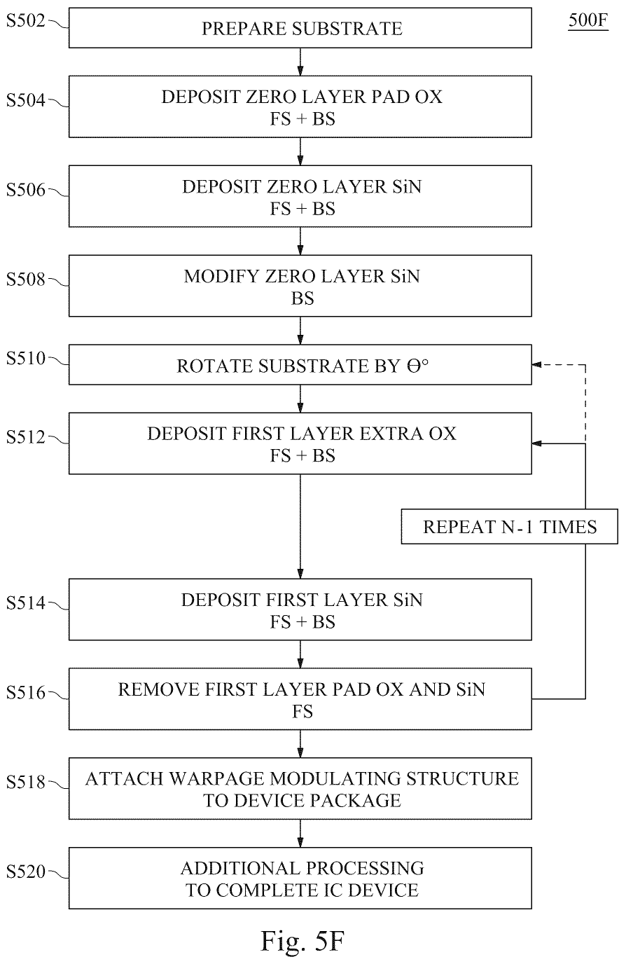

FIGS. 5A-E are cross-sectional views of a stress and warpage modulating structure (SWM structure) during a manufacturing process, according to some embodiments. In FIG. 5A a semiconductor substrate 102 is prepared and a frontside pad oxide layer 104_{f0} and a backside pad oxide layer 104_{b0} are formed on opposing sides of the semiconductor substrate. The pad oxide layers will typically be formed using one or more of the processes discussed above in connection with FIG. 1A and, in some embodiments, will comprise suitable materials in addition to or other than silicon dioxide. In some embodiments the frontside pad oxide layer 104_{f0} and a backside pad oxide layer 104_{b0} have a thickness of about 40 Å although pad oxide layers having other thicknesses are used in some embodiments.

A frontside silicon nitride layer 106_{f0} and a backside silicon nitride layer 106_{b0} are then formed on the corresponding frontside pad oxide layer 104_{f0} and a backside pad oxide layer 104_{b0}. In some embodiments the silicon nitride layers have a thickness of about 380 Å although layers having other thicknesses are used in some embodiments. The silicon nitride layers will typically be formed using a process using one or more of the processes discussed above in connection with FIG. 1A and, in some embodiments, will comprise suitable materials in addition to or other than silicon nitride. The semiconductor substrate 102, in combination with the frontside pad oxide layer 104_{f0}, the backside pad oxide layer 104_{b0}, the frontside silicon nitride layer 106_{f0}, and the backside silicon nitride layer 106_{b0} comprise a zero layer structure 500A.

In FIG. 5B, the zero layer structure 500A is modified by the implanting oxygen into the backside silicon nitride layer 106_{b0} to obtain a SiON composition (alternatively SiN:OX) forming a backside SiN:OX layer 112_{b0} in place of the initially formed backside silicon nitride layer 106_{b0} to form a modified zero layer structure 500B. In some embodiments the backside SiN:OX layer 112_{b0} will have a thickness similar to that of the initially deposited of about 380 Å although layers having other thicknesses are used in some embodiments.

In FIG. 5C, the modified zero layer structure 500B is then modified by the addition of a first frontside extra oxide layer 104_{f1}, a first backside extra oxide layer 104_{b1}, and a first frontside silicon nitride layer 106_{f1} to form a first layer structure 500C. In some embodiments the first frontside extra oxide layer 104_{f1} has a thickness of about 20-200 Å, e.g., 40 Å, although layers having other thicknesses are used in some embodiments. The intermediate SWM structure 500B is further modified by the addition of a first backside silicon nitride layer 106_{b1} that is formed over the first backside extra oxide layer 104_{b1} on the backside of the intermediate SWM structure 500B to obtain the first layer structure 500C. In some embodiments the first frontside silicon nitride layer 106_{f1} and first backside silicon nitride layer 106_{b1} have a thickness of about 200-2000 Å, e.g., 800 Å, although one or both of the first silicon nitride layers having other thicknesses are used in some embodiments. In some embodiments the intermediate SWM structure 500B is rotated to a predetermined offset angle that is Θ degrees offset from the orientation used during formation of the underlying layer(s) between the formation of successive layers. In some embodiments the offset angle is between 0° and 90°. In some embodiments, successive depositions are conducted at offset angles of 15°, 30°, 45°, 60°, 75°, or 90°.

In FIG. 5D, the first layer structure 500C is modified by removing the first frontside extra oxide layer 104_{f1} and a first frontside silicon nitride layer 106_{f1} to form an intermediate SWM structure 500D. In some embodiments, the extra oxide and silicon nitride layers are removed using a dry-etch, plasma etch, and/or wet etch processes as detailed above with reference to FIG. 1C.

In FIG. 5E, the intermediate SWM structure 500D is further modified by the repeated formation of additional N−1 frontside extra oxide layers 104_{fN-1}, backside extra oxide layers 104_{bN-1}, frontside silicon nitride layers 106_{fN-1}, and backside silicon nitride layers 106_{bN-1} as detailed above with reference to FIG. 5D. The additional depositions are then followed by removing each of the additional N−1 frontside extra oxide layers 104_{fN-1} and frontside silicon nitride layers 106_{fN-1} to form SWM structure 500E in which the backside of the SWM structure 500E includes N layers of alternating layers of backside extra oxide layers 104_{bN} and backside silicon nitride layers 106_{bN}. In some embodiments, the thicknesses of the alternating layers of backside extra oxide layers 104_{bN} and backside silicon nitride layers 106_{bN} are constant while in other embodiments one or both of the alternating layers of backside extra oxide layers 104_{bN} and backside silicon nitride layers 106_{bN} have varied thicknesses, e.g., increasing thickness of the backside silicon nitride layers from the first backside silicon nitride layer 106_{b1} to 106_{bN} the first backside silicon nitride layer. In some embodiments, the extra oxide and silicon nitride layers are removed using a dry-etch, plasma etch, and/or wet etch processes as detailed above with reference to FIG. 5D.

FIG. 5F is a flowchart of a portion of a manufacturing process 500F for the production of SWM structures according to some embodiments of the structures of FIGS. 5A-E including operation S502 during which the semiconductor substrate is prepared for pad oxide deposition, operation S504 during which the zero layer pad oxide layers are formed on both the frontside (FS) and backside (BS) surfaces of the semiconductor substrate 102 and operation S506 during which the zero layer silicon nitride layers are formed on both the FS and BS surfaces of the semiconductor substrate 102 to complete the zero layer structure 500A. In operation S508 the BS silicon nitride layer of the zero layer structure 500A is implanted with oxygen to convert the initially deposited silicon nitride into a SiN:OX material and form the modified zero layer structure 500B. In optional operation S510 the modified zero layer structure 500B is rotated to an offset angle of Θ°, e.g., 45°, after which first layer extra oxide is formed on the FS of the intermediate SWM structure 500B in operation S512. In operation S514 the first silicon nitride layers are formed on the FS and BS of the modified zero layer structure 500B to form a first layer structure 500C. In operation S516 the first layer silicon nitride and the first layer extra oxide are removed from the FS of the first layer structure 500C to form an intermediate SWM structure 500D. The intermediate SWM structure 500D is then further modified with the repeated application of operations S512-S516 (and optionally, operation S510) to form a series of alternating layers of silicon oxide and silicon nitride on the backside of the intermediate SWM structure 500D. After a predetermined number (N−1) additional alternating layers are formed the SWM structure 500E is complete and can be utilized in multi-stacked die/wafer and wafer/wafer packaging assemblies comprising, e.g., systems of integrated chips (SOIC) and chip on wafer on substrate (CoWoS) packaging configurations.

The performance of the SWM structures within a multi-stacked die/wafer and wafer/wafer packaging assembly is a function of the configuration of the particular SWM structure including, for example, the thickness of the semiconductor substrate, the thickness and number of the silicon dioxide layers remaining on the frontside and backside of the semiconductor substrate, the thickness and number of the silicon nitride layers remaining on the frontside and backside of the semiconductor substrate. Other factors will include the manner of construction of the layers present, the angular offsets used between adjacent deposition layers, the presence of one or more modified deposition layers, e.g., SiN:OX layers, and the method and materials used to attach the SWM structure to a structure within the multi-stacked die/wafer or wafer/wafer packaging assembly. When properly utilized some embodiments of the SWM structures will improve the uniformity of the deposited layers and avoid stress cracking that provide channels to underlying layers and compromise etch processes.

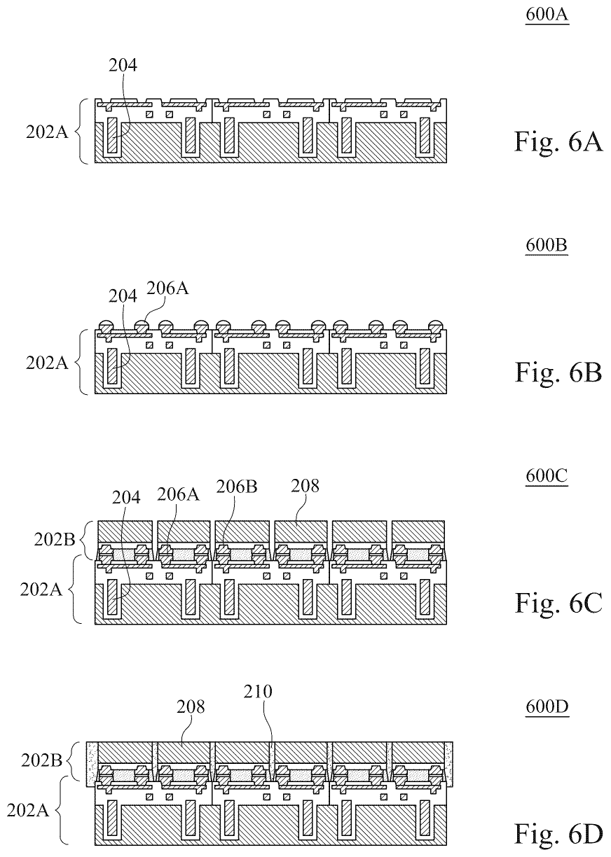

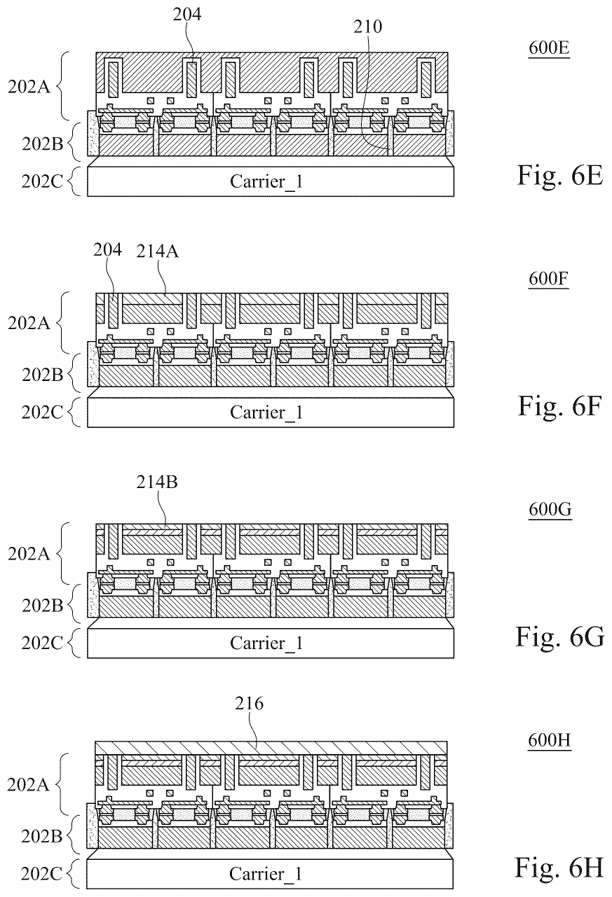

FIGS. 6A-H are cross-sectional views of a multi-stack wafer/die level package during a manufacturing process that incorporates a SWM structure according to some embodiments. FIG. 6A is a cross-sectional view of a first semiconductor device 202A after the addition of an interposer and formation of through silicon vias 204 (TSV). FIG. 6B is a cross-sectional view reflecting the results of a subsequent operation during which μ-bump structures, e.g., copper bumps 206A have been formed on the frontside of the first semiconductor device 202A. FIG. 6C is a cross-sectional view of an assembly including a second semiconductor device 202B comprising one or more semiconductor die 208 and a corresponding plurality of copper bumps 206B that has been inverted and mounted, frontside-to-frontside onto the first semiconductor device 202A using, in some embodiments, frontside die-to-wafer (D2W) bonding processes. In some embodiments, an underfill material 210 is used for filing spaces between the components or elements that are configured as the second semiconductor device 202B as shown in FIG. 6C.

In some embodiments, the assembly comprising the first semiconductor device 202A and the second semiconductor device 202B are inverted and a carrier 202C is mounted on the backside of the second semiconductor device as shown in FIG. 6E. As shown in FIG. 6F, a portion of the backside of the first semiconductor device 202A is removed to thin the assembly and expose a lower surface (relative to the first semiconductor device) of the TSVs. In some embodiments as shown in FIGS. 6F and 6G a backside portion of the semiconductor dies 208 is removed and replaced with, e.g., a silicon oxide layer 214A or a combination of silicon oxide and silicon nitride 214B. As shown in FIG. 6H, in some embodiments a stress and warpage modulating (SWM) structure 216 is then mounted on the backside of the first semiconductor device 202A for reducing the detrimental effects associated with stress, strain, and warpage on the performance and/or lifetime of the resulting multi-stack package.

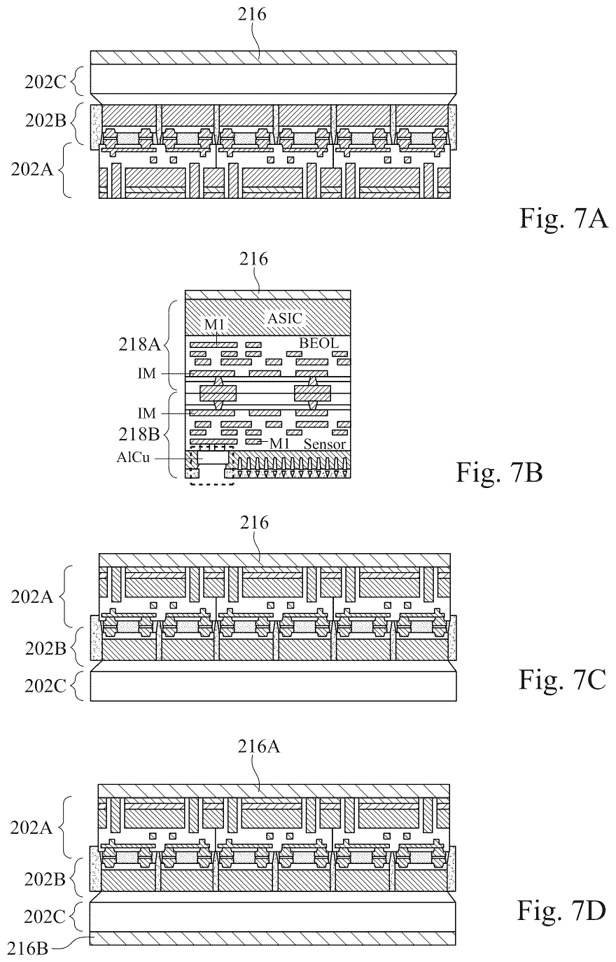

FIGS. 7A-D are cross-sectional views of embodiments of multi-stack wafer/die level packages incorporating a SWM structure. Embodiments of multi-stack wafer/die level packages according to FIG. 7A are configured to incorporate a SWM structure 216 by mounting the SWM structure on a backside carrier 202C. Embodiments of multi-stack wafer/die level packages according to FIG. 7A are configured to incorporate a SWM structure 216 by mounting the SWM structure on a backside carrier 202C. Embodiments of multi-stack wafer/wafer level packages according to FIG. 7B are configured to incorporate a SWM structure 216 by mounting the SWM structure 216 on a backside surface of a first wafer 218A. Embodiments of multi-stack wafer/wafer level packages according to FIG. 7C are configured to incorporate a SWM structure 216 by mounting the SWM structure 216 on a backside surface of a first semiconductor device 202A opposite an included carrier. Embodiments of multi-stack wafer/wafer level packages according to FIG. 7D are configured to incorporate a SWM structure 216 by mounting a first SWM structure 216A on a backside surface of a first semiconductor device 202A opposite an included carrier and a second SWM structure 216B on a carrier 202C.

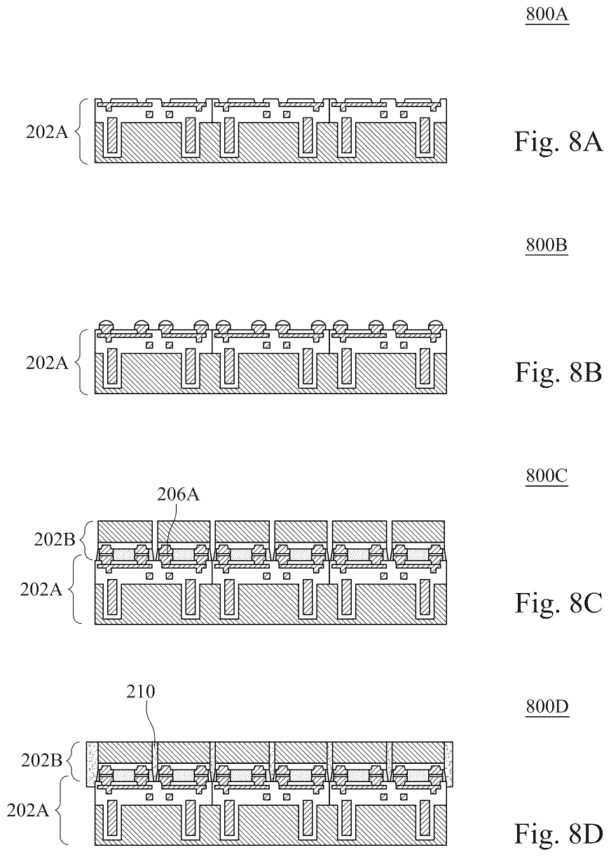

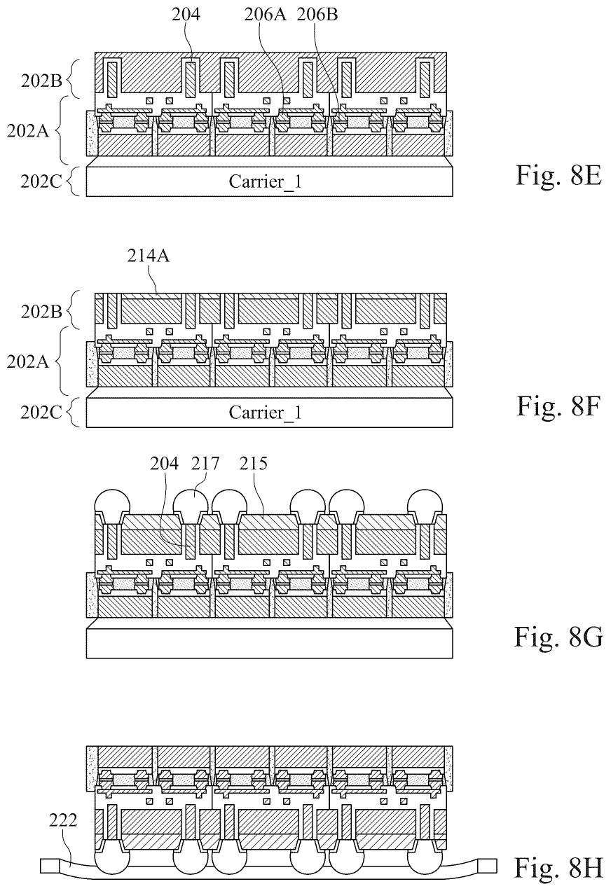

FIGS. 8A-H are cross-sectional views of a multi-stack wafer/die level package during a manufacturing process that incorporates a SWM structure according to some embodiments. FIG. 8A is a cross-sectional view of a first semiconductor device 202A after the addition of an interposer and formation of through silicon vias 204 (TSV). FIG. 8B is a cross-sectional view reflecting the results of a subsequent operation during which μ-bump structures, e.g., copper bumps 206A have been formed on the frontside of the first semiconductor device 202A. FIG. 8C is a cross-sectional view of an assembly including a second semiconductor device 202B comprising one or more semiconductor die 208 and a corresponding plurality of copper bumps 206B that has been inverted and mounted, frontside-to-frontside onto the first semiconductor device 202A using, in some embodiments, frontside die-to-wafer (D2W) bonding processes. In some embodiments, an underfill material 210 is used for filing spaces between the components or elements including the semiconductor die 208 that are configured as the second semiconductor device 202B as shown in FIG. 8D.

In some embodiments, the assembly comprising the first semiconductor device 202A and the second semiconductor device 202B are inverted and a carrier 202C is mounted on the backside of the second semiconductor device as shown in FIG. 8E. As shown in FIG. 8F, a portion of the backside of the first semiconductor device 202A is removed to thin the assembly and expose a lower surface (relative to the first semiconductor device) of the TSVs. In some embodiments as shown in FIG. 8F a backside portion of the semiconductor dies 208 is removed and replaced with, e.g., a silicon oxide layer 214A or a combination of silicon oxide and silicon nitride 214B (not shown) that provides a local SWM structure. As shown in FIG. 8G, in some embodiments a passivation layer 215 is added to the backside of the first semiconductor device 202A and then patterned and etched so that contact bumps 217 can be formed on the TSVs 214. As shown in FIG. 8H, in some embodiments the carrier 202C is removed and the composite package counted on a dicing frame 222. a stress and warpage modulating (SWM) structure 216 is then mounted on the backside of the first semiconductor device 202A for reducing the detrimental effects associated with stress, strain, and warpage on the performance and/or lifetime of the resulting multi-stack package.

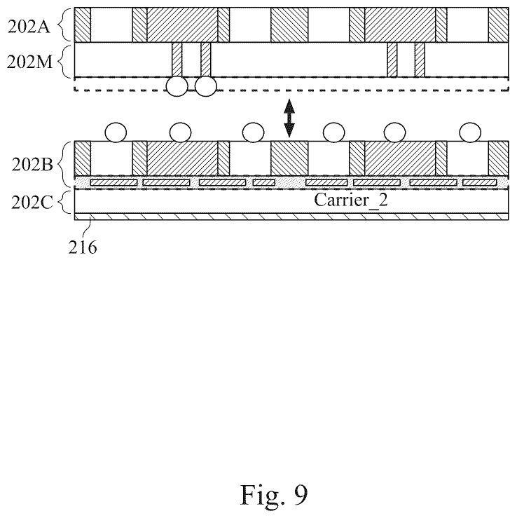

FIG. 9 is a cross-sectional view of a multi-stack wafer/die system of integrated chips (SOIC) package during a manufacturing process that incorporates a SWM structure according to some embodiments. The composite multi-stack package of FIG. 9 includes a first semiconductor device 202A, a multilayer interconnection structure 202M including a sequence of metal patterns separated by interlayer dielectric layers (not shown) and vias 219 added to the first semiconductor device during backend of line (BEOF) processing, a second semiconductor device 202B, a carrier 202C, and a SWM structure 216 mounted on a backside of the carrier that will reduce the mechanical and thermal stress experienced by the active components and improve the performance and/or lifetime of the multi-stack assembly. In some embodiments a via 219 extending through the carrier 202C and the second semiconductor device 202B provides an electrical connection between frontside and backside circuits.

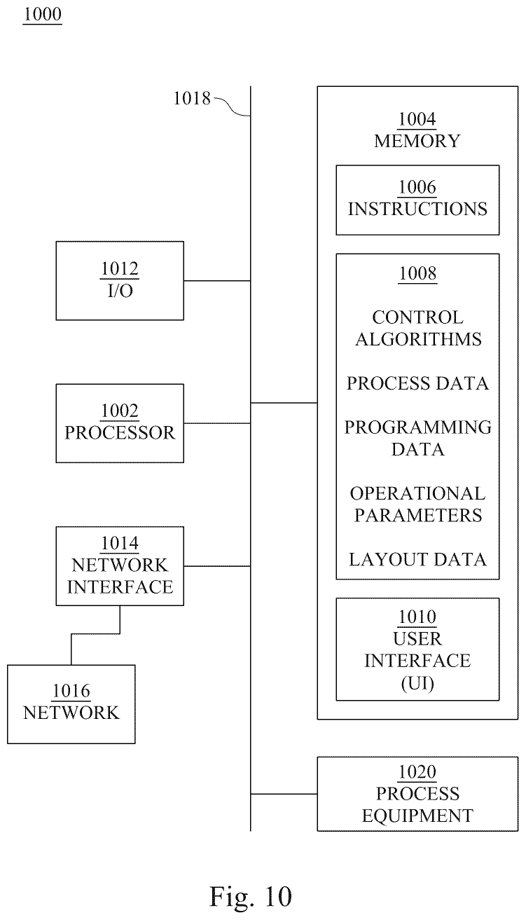

FIG. 10 is a block diagram of an electronic process control (EPC) system 1000, in accordance with some embodiments. Methods used for generating cell layout diagrams corresponding to some embodiments of the FET device structures detailed above, particularly with respect to the addition and placement of the electrical contacts, thermal contacts, active metal patterns, dummy metal patterns, and other heat dissipating structures may be implemented, for example, using EPC system 1000, in accordance with some embodiments of such systems.

In some embodiments, EPC system 1000 is a general purpose computing device including a hardware processor 1002 and a non-transitory, computer-readable, storage medium 1004. Computer-readable storage medium 1004, amongst other things, is encoded with, i.e., stores, computer program code (or instructions) 1006, i.e., a set of executable instructions. Execution of computer program code 1006 by hardware processor 1002 represents (at least in part) an EPC tool which implements a portion or all of, e.g., the methods described herein in accordance with one or more (hereinafter, the noted processes and/or methods).

Hardware processor 1002 is electrically coupled to computer-readable storage medium 1004 via a bus 1018. Hardware processor 1002 is also electrically coupled to an I/O interface 1012 by bus 1018. A network interface 1014 is also electrically connected to hardware processor 1002 via bus 1018. Network interface 1014 is connected to a network 1016, so that hardware processor 1002 and computer-readable storage medium 1004 are capable of connecting to external elements via network 1016. Hardware processor 1002 is configured to execute computer program code 1006 encoded in computer-readable storage medium 1004 in order to cause the EPC system 1000 to be usable for performing a portion or all of the noted processes and/or methods. In one or more embodiments, hardware processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, computer-readable storage medium 1004 stores computer program code 1006 configured to cause the EPC system 1000 (where such execution represents (at least in part) the EPC tool) to be usable for performing a portion or all of the noted processes and/or methods. In one or more embodiments, computer-readable storage medium 1004 also stores information which facilitates performing a portion or all of the noted processes and/or methods. In one or more embodiments, computer-readable storage medium 1004 stores process control data 1008 including, in some embodiments, control algorithms, process variables and constants, target ranges, set points, programming control data, and code for enabling statistical process control (SPC) and/or model predictive control (MPC) based control of the various processes.

EPC system 1000 includes I/O interface 1012. I/O interface 1012 is coupled to external circuitry. In one or more embodiments, I/O interface 1012 includes a keyboard, keypad, mouse, trackball, trackpad, touchscreen, and/or cursor direction keys for communicating information and commands to hardware processor 1002.

EPC system 1000 also includes network interface 1014 coupled to hardware processor 1002. Network interface 1014 allows EPC system 1000 to communicate with network 1016, to which one or more other computer systems are connected. Network interface 1014 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EPC systems 1000.

EPC system 1000 is configured to send information to and receive information from fabrication tools 1020 that include one or more of ion implant tools, etching tools, deposition tools, coating tools, rinsing tools, cleaning tools, chemical-mechanical planarizing (CMP) tools, testing tools, inspection tools, transport system tools, and thermal processing tools that will perform a predetermined series of manufacturing operations to produce the desired integrated circuit devices. The information includes one or more of operational data, parametric data, test data, and functional data used for controlling, monitoring, and/or evaluating the execution, progress, and/or completion of the specific manufacturing process. The process tool information is stored in and/or retrieved from computer-readable storage medium 1004.

EPC system 1000 is configured to receive information through I/O interface 1012. The information received through I/O interface 1012 includes one or more of instructions, data, programming data, design rules that specify, e.g., layer thicknesses, spacing distances, structure and layer resistivity, and feature sizes, process performance histories, target ranges, set points, and/or other parameters for processing by hardware processor 1002. The information is transferred to hardware processor 1002 via bus 1018. EPC system 1000 is configured to receive information related to a user interface (UI) through I/O interface 1012. The information is stored in computer-readable medium 1004 as user interface (UI) 1010.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EPC tool. In some embodiments, a portion or all of the noted processes and/or methods is implemented as a software application that is used by EPC system 1000.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

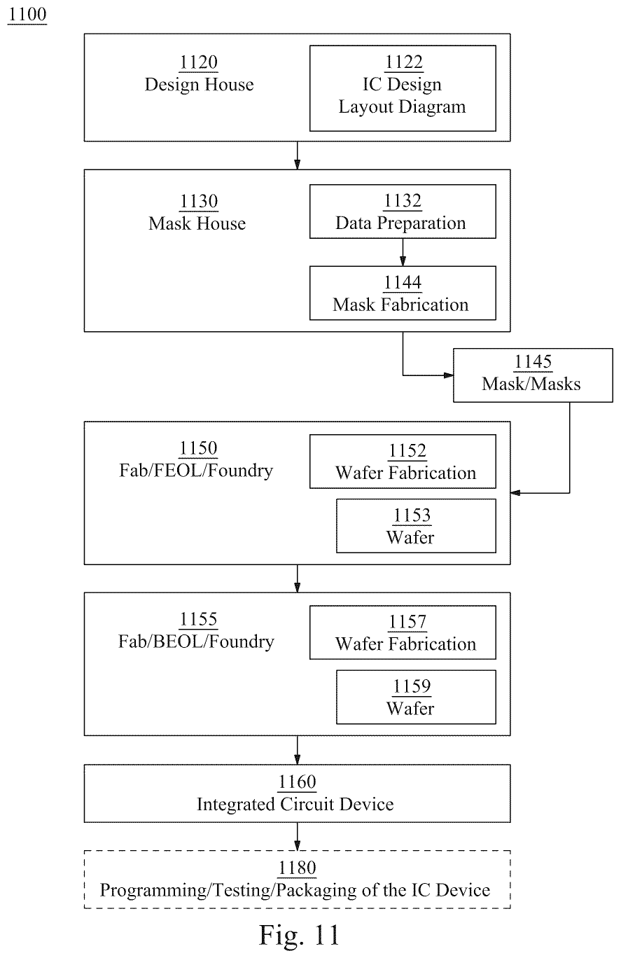

FIG. 11 is a block diagram of an integrated circuit (IC) manufacturing system 1100, and an IC manufacturing flow associated therewith, in accordance with some embodiments for manufacturing IC devices that incorporate the improved control over the SSD and EPI profile. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. Once the manufacturing process has been completed to form a plurality of IC devices on a wafer, the wafer is optionally sent to backend or back end of line (BEOL) 1180 for, depending on the device, programming, electrical testing, and packaging in order to obtain the final IC device products. The entities in manufacturing system 1100 are connected by a communications network. In some embodiments, the communications network is a single network. In some embodiments, the communications network is a variety of different networks, such as an intranet and the Internet.

The communications network includes wired and/or wireless communication channels. Each entity interacts with one or more of the other entities and provides services to and/or receives services from one or more of the other entities. In some embodiments, two or more of design house 1120, mask house 1130, and IC Fab 1150 is owned by a single larger company. In some embodiments, two or more of design house 1120, mask house 1130, and IC Fab 1150 coexist in a common facility and use common resources.

Design house (or design team) 1120 generates an IC design layout diagram 1122. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features.

For example, a portion of IC design layout diagram 1122 includes various IC features, such as an active region, gate electrode, source and drain, metal lines or vias of an intermetal interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122, in some operations, will be expressed in a GDSII file format or DFII file format.

Whereas the pattern of a modified IC design layout diagram is adjusted by an appropriate method in order to, for example, reduce parasitic capacitance of the integrated circuit as compared to an unmodified IC design layout diagram, the modified IC design layout diagram reflects the results of changing positions of conductive line in the layout diagram, and, in some embodiments, inserting to the IC design layout diagram, features associated with capacitive isolation structures to further reduce parasitic capacitance, as compared to IC structures having the modified IC design layout diagram without features for forming capacitive isolation structures located therein.

Mask house 1130 includes mask data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The IC design layout diagram 1122 is manipulated by mask data preparation 1132 to comply with particular characteristics of the mask writer and/or requirements of IC Fab 1150. In FIG. 11, mask data preparation 1132 and mask fabrication 1144 are illustrated as separate elements. In some embodiments, mask data preparation 1132 and mask fabrication 1144 are collectively referred to as mask data preparation.

In some embodiments, mask data preparation 1132 includes optical proximity correction (OPC) which uses lithography enhancement techniques to compensate for image errors, such as those that are known to arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC Fab 1150 to fabricate IC device 1160. LPC simulates this processing based on IC design layout diagram 1122 to create a simulated manufactured device, such as IC device 1160. In some embodiments, the processing parameters in LPC simulation will include parameters associated with various processes of the IC manufacturing cycle, parameters associated with tools used for manufacturing the IC, and/or other aspects of the manufacturing process. LPC accounts for various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, mask data preparation 1132 includes additional features such as a logic operation (LOP) to modify the IC design layout diagram 1122 according to manufacturing rules. Additionally, the processes applied to IC design layout diagram 1122 during mask data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 will be formed using a process selected from various available technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask.

In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask will be attenuated PSM or alternating PSM. The mask(s) generated by mask fabrication 1144 is used in a variety of processes. For example, such a mask(s) is/are used in an ion implantation process to form various doped regions in semiconductor wafer 1153, in an etching process to form various etching regions in semiconductor wafer 1153, and/or in other suitable processes.

IC Fab 1150 includes wafer fabrication 1152. IC Fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

Wafer fabrication 1152 includes forming a patterned layer of mask material formed on a semiconductor substrate is made of a mask material that includes one or more layers of photoresist, polyimide, silicon oxide, silicon nitride (e.g., Si₃N₄, SiON, SiC, SiOC), or combinations thereof. In some embodiments, masks 1145 include a single layer of mask material. In some embodiments, a mask 1145 includes multiple layers of mask materials.

In some embodiments IC Fab 1155 includes wafer fabrication 1157. IC Fab 1155 is an IC fabrication business that includes one or more manufacturing facilities for the fabrication of a variety of different IC products. In some embodiments, IC Fab 1155 is a manufacturing facility provide the back end fabrication for the interconnection and packaging of the IC products (back-end-of-line (BEOL) fabrication) to add one or more metallization layers to wafer 1159, and a third manufacturing facility (not shown) may provide other services for the foundry business such as packaging and labelling.

In some embodiments, the mask material is patterned by exposure to an illumination source. In some embodiments, the illumination source is an electron beam source. In some embodiments, the illumination source is a lamp that emits light. In some embodiments, the light is ultraviolet light. In some embodiments, the light is visible light. In some embodiments, the light is infrared light. In some embodiments, the illumination source emits a combination of different (UV, visible, and/or infrared) light.

In some embodiments, etching processes include presenting the exposed structures in the functional area(s) to an oxygen-containing atmosphere to oxidize an outer portion of the exposed structures, followed by a chemical trimming process such as plasma-etching or liquid chemical etching, as described above, to remove the oxidized material and leave behind a modified structure. In some embodiments, oxidation followed by chemical trimming is performed to provide greater dimensional selectivity to the exposed material and to reduce a likelihood of accidental material removal during a manufacturing process. In some embodiments, the exposed structures may include the fin structures of Fin Field Effect Transistors (FinFET) with the fins being embedded in a dielectric support medium covering the sides of the fins. In some embodiments, the exposed portions of the fins of the functional area are top surfaces and sides of the fins that are above a top surface of the dielectric support medium, where the top surface of the dielectric support medium has been recessed to a level below the top surface of the fins, but still covering a lower portion of the sides of the fins.

Subsequent to mask patterning operations, areas not covered by the mask are etched to modify a dimension of one or more structures within the exposed area(s). In some embodiments, the etching is performed using plasma etching, reactive ion etching (RIE), or a liquid chemical etch solution, according to some embodiments. The chemistry of the liquid chemical etch solution includes one or more of etchants such as citric acid (C₆H₈O₇), hydrogen peroxide (H₂O₂), nitric acid (HNO₃), sulfuric acid (H₂SO₄), hydrochloric acid (HCl), acetic acid (CH₃CO₂H), hydrofluoric acid (HF), buffered hydrofluoric acid (BHF), phosphoric acid (H₃PO₄), ammonium fluoride (NH₄F) potassium hydroxide (KOH), ethylenediamine pyrocatechol (EDP), TMAH (tetramethylammonium hydroxide), or a combination thereof.

In some embodiments, the etching process is a dry-etch or plasma etch process. Plasma etching of a substrate material is performed using halogen-containing reactive gasses excited by an electromagnetic field to dissociate into ions. Reactive or etchant gases include, for example, CF₄, SF₆, NF₃, Cl₂, CCl₂F₂, SiCl₄, BCl₂, or a combination thereof, although other semiconductor-material etchant gases are also envisioned within the scope of the present disclosure. Ions are accelerated to strike exposed material by alternating electromagnetic fields or by fixed bias according to methods of plasma etching that are known in the art.

In some embodiments, molecular level processing technologies that share the self-limiting surface reaction characteristics utilized in ALD including, for example, Molecular Layer Deposition (MLD) and Self-Assembled Monolayers (SAM). MLD utilizes successive precursor-surface reactions in which a precursor is introduced into a reaction zone above the wafer surface. The precursor adsorbs to the wafer surface where it is confined by physisorption. The precursor then undergoes a quick chemisorption reaction with a number of active surface sites, leading to the self-limiting formation of molecular attachments in specific assemblies or regularly recurring structures. These MLD structures will be formed successfully using lower process temperatures than some traditional deposition techniques.

SAM is a deposition technique that involves the spontaneous adherence of organized organic structures on a wafer surface. This adherence involves adsorption of the organic structures from the vapor or liquid phase utilizing relatively weak interactions with the wafer surface. Initially, the structures are adsorbed on the surface by physisorption through, for instance, van der Waals forces or polar interactions. The self-assembled monolayers will then become confined to the surface by a chemisorption process. In some embodiments, the ability of SAM to grow layers as thin as a single molecule through chemisorption-driven interactions with the wafer surface(s) will be particularly useful in forming thin films including, for example, “near-zero-thickness” activation or barrier layers. SAM will also be particularly useful in area-selective deposition (ASD) (or area-specific deposition) using molecules that exhibit preferential reactions with specific segments of the underlying wafer surface in order to facilitate or obstruct subsequent material growth in the targeted areas. In some embodiments, SAM is used to form a foundation or blueprint region for subsequent area-selective ALD (AS-ALD) or area-selective CVD (AS-CVD).

The ALD, MLD, and SAM processes represent viable options for manufacturing thin layers (in some embodiments, the manufactured layers are only few atoms thick) that exhibit sufficient uniformity, conformality, and/or purity for the intended IC device application. By delivering the constituents of the material systems being manufactured both individually and sequentially into the processing environment, these processes and the precise control of the resulting surface chemical reactions allow for excellent control of processing parameters and the target composition and performance of the resulting film(s).

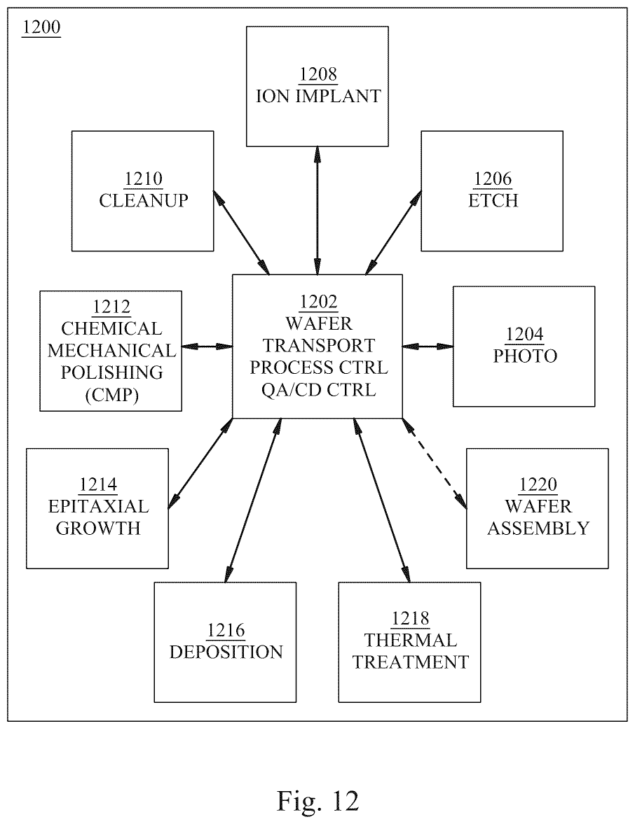

FIG. 12 is a schematic diagram of various processing departments defined within a Fab/Front End/Foundry for manufacturing IC devices according to some embodiments. The processing departments utilized in both front end of line (FEOL) and back end of line (BEOL) IC device manufacturing typically include a wafer transport operation 1202 for moving the wafers between the various processing departments. In some embodiments, the wafer transport operation will be integrated with an electronic process control (EPC) system according to FIG. 5 and utilized for providing process control operations, ensuring that the wafers being both processed in a timely manner and sequentially delivered to the appropriate processing departments as determined by the process flow. In some embodiments, the EPC system will also provide control and/or quality assurance and parametric data for the proper operation of the defined processing equipment. Interconnected by the wafer transport operation 1202 will be the various processing departments providing, for example, photolithographic operations 1204, etch operations 1206, ion implant operations 1208, clean-up/strip operations 1210, chemical mechanical polishing (CMP) operations 1212, epitaxial growth operations 1214, deposition operations 1216, thermal treatments 1218, and, in some embodiments, wafer assembly 1220 during which two or more substrates are joined to form a final device substrate structure.

In some embodiments a stress modulating device includes a semiconductor substrate, a first insulating layer formed over a first side of the semiconductor substrate, a second insulating layer formed over the first insulating layer, a third insulating layer formed over a second side of the semiconductor substrate, a fourth insulating layer formed over the third insulating layer, and a fifth insulating layer formed over the fourth insulating layer.

Some embodiments of stress modulating devices also include one or more additional elements selected from a group including a first insulating layer and a third insulating layer having a first composition with a second insulating layer and a fourth insulating layer having a second composition that is distinct from the first composition, a fifth insulating layer having the second composition; first and third insulating layers including silicon dioxide and second, fourth, and fifth insulating layers including silicon nitride; a fourth insulating layer formed from a composition corresponding to SiₓO_{y}N_{z} in which 1≤x≤3, 0<y≤2, and 0<z≤4, a series of N−1 alternating layers of the first and second compositions; and/or a series of N−1 alternating layers of silicon dioxide and silicon nitride formed over the fifth insulating layer.

In some embodiments of methods of manufacturing stress modulating devices includes preparing a semiconductor substrate, forming first and second insulating layers over a first side of the semiconductor substrate, forming a second insulating layer over the first insulating layer, forming a third, fourth, and fifth insulating layer over a second side of the semiconductor substrate.

Some embodiments of methods of manufacturing stress modulating devices also include one or more additional elements selected from a group including the operations of forming the first insulating layer by depositing a film including silicon dioxide, forming the second insulating layer by depositing a film including silicon nitride, forming the third insulating layer by depositing a film including silicon dioxide, forming the fourth insulating layer by depositing a film including silicon nitride, and forming the fifth insulating layer by depositing a film including silicon nitride; depositing a silicon dioxide film between the fourth insulating layer and the fifth insulating layer; modifying the fourth insulating layer with oxygen to form a SiON composition before forming the fifth insulating layer; rotating the semiconductor substrate by Θ° after forming the third insulating layer and before forming the fourth insulating layer; rotating the semiconductor substrate by Θ° comprises rotating the semiconductor substrate by 45°; and/or depositing a series of N−1 alternating layers of a first layer comprising silicon dioxide and a second layer comprising silicon nitride over the fifth insulating layer; forming a series of N−1 alternating layers of silicon dioxide and silicon nitride formed over the first side of the semiconductor substrate, forming a series of N−1 alternating layers of silicon dioxide and silicon nitride formed over the second side of the semiconductor substrate, and removing each of the series of N−1 alternating layers of silicon dioxide and silicon nitride formed over the first side of the semiconductor substrate before depositing an addition one of the series of N−1 alternating layers of silicon dioxide and silicon nitride.

Some embodiments of multi-layer semiconductor package assemblies include a first semiconductor device, a second semiconductor device mounted on the first semiconductor device for establishing electrical connections between the first and second semiconductor devices with the first semiconductor device and the second semiconductor device having an initial stress load, and a first stress modulating device that reduces the initial stress load with the first stress modulating device including a semiconductor substrate, a first insulating layer on a first side of the semiconductor substrate, a second insulating layer on the first insulating layer, a third insulating layer on a second side of the semiconductor substrate, a fourth insulating layer on the third insulating layer, and a fifth insulating layer on the fourth insulating layer.

Some embodiments of multi-layer semiconductor package assemblies also include one or more additional elements or configurations selected from a group including a carrier mounted on the second semiconductor device, wherein the first stress modulating device is mounted on the carrier and reduces the initial stress load; the first stress modulating device is mounted on the first semiconductor device; a second stress modulating device mounted on the first semiconductor device, wherein the combination of the first stress modulating device and the second stress modulating device further reduces the initial stress load; and/or the first and second semiconductor devices are independently selected from semiconductor wafers and semiconductor dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A stress modulating device comprising:
a semiconductor substrate;
a first insulating layer over a first side of the semiconductor substrate;
a second insulating layer over the first insulating layer;
a third insulating layer over a second side of the semiconductor substrate;
a fourth insulating layer over the third insulating layer; and
a fifth insulating layer over the fourth insulating layer, wherein the stress modulating device is substantially free of conductive materials.

2. The stress modulating device of claim 1, wherein:
the first insulating layer and the third insulating layer have a first composition; and
the second insulating layer and the fourth insulating layer have a second composition, wherein the first composition is different than the second composition.

3. The stress modulating device of claim 2, wherein:
the fifth insulating layer has the second composition.

4. The stress modulating device of claim 1, wherein:
the first insulating layer and the third insulating layer comprise silicon dioxide; and
the second insulating layer, the fourth insulating layer, and the fifth insulating layer comprise silicon nitride.

5. The stress modulating device of claim 2, wherein:
the first insulating layer and the third insulating layer comprise silicon dioxide;
the second insulating layer and the fifth insulating layer comprise silicon nitride; and
the fourth insulating layer comprises a SiₓO_{y}N_{z} composition wherein 1≤x≤3, 0<y≤2, and 0<z≤4.

6. The stress modulating device of claim 2, further comprising:
a series of N−1 alternating layers of the first composition and the second composition.

7. The stress modulating device of claim 5, further comprising:
a series of N−1 alternating layers of silicon dioxide and silicon nitride formed over the fifth insulating layer.

8. A method of manufacturing a stress modulating device comprising:
forming a first insulating material over a first side and a second side of a semiconductor substrate;
forming a second insulating material over the first insulating layer on the first side and the second side of the semiconductor substrate;
forming a third insulating material over the second insulating material on the second side of the semiconductor substrate; and
forming a fourth insulating layer over the second insulating material on the first side of the semiconductor substrate and over the third insulating layer on the second side of the semiconductor substrate.

9. The method according to claim 8, wherein:
forming the first insulating material comprises depositing a film comprising silicon dioxide;
forming the second insulating material comprises depositing a film comprising silicon nitride;
forming the third insulating material comprises depositing a film comprising silicon dioxide; and
forming the fourth insulating material comprises depositing a film comprising silicon nitride.

10. The method according to claim 9, further comprising:
depositing the second insulating material to form a first layer having a first thickness T₁; and
depositing the fourth insulating material to form a second layer having a second thickness T₂, wherein the first thickness and the second thickness satisfy an expression T₂>T₁.

11. The method according to claim 9, further comprising:
modifying the third insulating material with oxygen to form a SiON composition before forming the fourth insulating material.

12. The method according to claim 8, further comprising:
rotating the semiconductor substrate by Θ° after forming the third insulating material and before forming the fourth insulating material.

13. The method according to claim 12, wherein:
rotating the semiconductor substrate by Θ° comprises rotating the semiconductor substrate by 45°.

14. The method according to claim 9, further comprising:
depositing a series of N−1 alternating layers of a first material comprising silicon dioxide and a second material comprising silicon nitride over the fourth insulating material.

15. The method according to claim 9, further comprising:
forming a series of N−1 alternating layers of silicon dioxide and silicon nitride formed over the first side of the semiconductor substrate;
forming a series of N−1 alternating layers of silicon dioxide and silicon nitride formed over the second side of the semiconductor substrate;
removing each of the series of N−1 alternating layers of silicon dioxide and silicon nitride formed over the first side of the semiconductor substrate; and
depositing a final one of the series of N−1 alternating layers of silicon dioxide and silicon nitride.

16. A multi-layer semiconductor package assembly comprising:
a first semiconductor device;
a second semiconductor device mounted on the first semiconductor device, wherein the first semiconductor device is electrically connected to the second semiconductor device,
wherein a combination of the first semiconductor device and the second semiconductor device has an initial stress load; and
a first stress modulating device configured to reduce the initial stress load, wherein the first stress modulating device comprises:
a semiconductor substrate;
a first insulating layer on a first side of the semiconductor substrate;
a second insulating layer on the first insulating layer;
a third insulating layer on a second side of the semiconductor substrate;
a fourth insulating layer on the third insulating layer; and
a fifth insulating layer on the fourth insulating layer.

17. The multi-layer semiconductor package assembly according to claim 16, further comprising:
a carrier mounted on the second semiconductor device, wherein the first stress modulating device is mounted on the carrier.

18. The multi-layer semiconductor package assembly according to claim 16, wherein:
the first stress modulating device is mounted on the first semiconductor device.

19. The multi-layer semiconductor package assembly according to claim 17, further comprising:
a second stress modulating device mounted on the first semiconductor device, wherein the second stress modulating device is configured to reduce the initial stress load.

20. The multi-layer semiconductor package assembly according to claim 16, wherein:
the first and second semiconductor devices are independently selected from the group consisting of semiconductor wafers and semiconductor die.
